(19) United States
(12) Patent Application Publication
(10) Pub. No.: US 2017/0140973 A1
(43) Pub. Date: May 18, 2017

(54) LAMINATE BODY AND COMPOSITE BODY; SEMICONDUCTOR DEVICE MANUFACTURING METHOD

(71) Applicant: NITTO DENKO CORPORATION, Osaka (JP)

(72) Inventors: Ryuichi KIMURA, Ibaraki-shi (JP); Naohide TAKAMOTO, Ibaraki-shi (JP)

(73) Assignee: NITTO DENKO CORPORATION, Osaka (JP)

(21) Appl. No.: 15/349,169

(22) Filed: Nov. 11, 2016

(30) Foreign Application Priority Data
Nov. 13, 2015 (JP) 2015-222896

(51) Int. Cl. H01L 21/683; B32B 27/38; B32B 27/30; H01L 21/78; B32B 7/12

(52) U.S. Cl. CPC H01L 21/6836; H01L 21/78; B32B 7/12; B32B 27/308; B32B 27/38; B32B 2255/26; B32B 2307/54; B32B 2457/14

(57) ABSTRACT

[PROBLEM] To provide a laminated body and so forth that makes it possible to reduce cracking that would otherwise occur at the chip side face during dicing.

[SOLUTION MEANS] This relates to a laminated body comprising a dicing sheet and a semiconductor backside protective film. The dicing sheet comprises a base layer and an adhesive layer arranged over the base layer. The semiconductor backside protective film is arranged over the adhesive layer. Tensile storage modulus of the semiconductor backside protective film following curing is not less than 1 GPa over the entire range 23° C. to 80° C.

### TECHNICAL FIELD

The present invention relates to a laminated body, a composite body, and a semiconductor device manufacturing method.

### BACKGROUND ART

Semiconductor backside protective films serve to reduce warpage of semiconductor waters and to protect the backsides thereof.

Methods in which semiconductor backside protective film and a dicing sheet are handled in integral fashion are known. For example, there is a method in which a semiconductor wafer is secured to a semiconductor backside protective film that is secured to a dicing sheet, an assembly comprising chips and diced semiconductor backside protective film is formed as a result of dicing thereof, and the assembly is detached from the dicing sheet.

### PRIOR ART REFERENCES

### Patent References

PATENT REFERENCE NO. 1: Japanese Patent Application Publication Kokai No. 2010-199541

### SUMMARY OF INVENTION

### Problem to be Solved by Invention

When using the aforementioned method, cracking may occur at the chip side face due to impact and friction occurring during dicing with a dicing saw. It is necessary to reduce chip side face cracking, i.e., sidewall chipping. This is because cracking detracts from outward appearance, and there is a possibility that it could impair reliability.

It is an object of the present invention to provide a laminated body that makes it possible to reduce cracking that would otherwise occur at the chip side face during dicing. It is an object of the present invention to provide a composite body that makes it possible to reduce cracking that would otherwise occur at the chip side face during dicing. It is an object of the present invention to provide a method for manufacturing a semiconductor device that makes it possible to reduce cracking that would otherwise occur at the chip side face during dicing.

### Means for Solving Problem

The present invention relates to a laminated body comprising a dicing sheet and a semiconductor backside protective film. The dicing sheet comprises a base layer and an adhesive layer arranged over the base layer. The semiconductor backside protective film is arranged over the adhesive layer. Tensile storage modulus of the semiconductor backside protective film following curing is not less than 1 GPa over the entire range 23° C. to 80° C. Because this is not less than 1 GPa, it is possible to reduce cracking that would otherwise occur at the chip side face during dicing.

The present invention also relates to a composite body comprising a release liner and a laminated body arranged over the release liner.

The present invention also relates to a semiconductor device manufacturing method that comprises an operation (A) in which a semiconductor wafer is secured to semiconductor backside protective film of a laminated body; an operation (B) in which, following Operation (A), the semiconductor backside protective film is cured; an operation (C) in which, following Operation (B), the semiconductor wafer secured to the semiconductor backside protective film is subjected to dicing to form an assembly; an operation (D) in which the assembly is detached from the dicing sheet. The assembly comprises a semiconductor chip and a post-dicing semiconductor backside protective film secured to the semiconductor chip. The semiconductor device manufacturing method of the present invention makes it possible to reduce cracking that would otherwise occur at the chip side face during dicing. This is so because tensile storage modulus of the semiconductor backside protective film following curing is not less than 1 GPa over the entire range 23° C. to 80° C., and dicing of the semiconductor wafer is carried out following Operation (B), the operation in which the semiconductor backside protective film is cured.

### BRIEF DESCRIPTION OF DRAWINGS

FIG. 1 Schematic plan view of a composite body.

FIG. 2 Schematic sectional diagram of a portion of a composite body.

FIG. 3 Schematic sectional diagram showing an operation for manufacturing a semiconductor device.

FIG. 4 Schematic sectional diagram showing an operation for manufacturing a semiconductor device.

FIG. 5 Schematic sectional diagram showing an operation for manufacturing a semiconductor device.

FIG. 6 Schematic sectional diagram showing the laminated body of Variation 1.

FIG. 7 Schematic sectional diagram of a laminated body and a wafer secured to the laminated body, showing depth to which a dicing blade cuts thereinto.

FIG. 8 A side view of an assembly—comprising a silicon chip and post-dicing semiconductor backside protective film—in accordance with a working example, showing crack depth.

### EMBODIMENTS FOR CARRYING OUT INVENTION

Although the present invention is described in detail below in terms of embodiments, it should be understood that the present invention is not limited only to these embodiments.

### Embodiment 1

### —Composite Body 1—

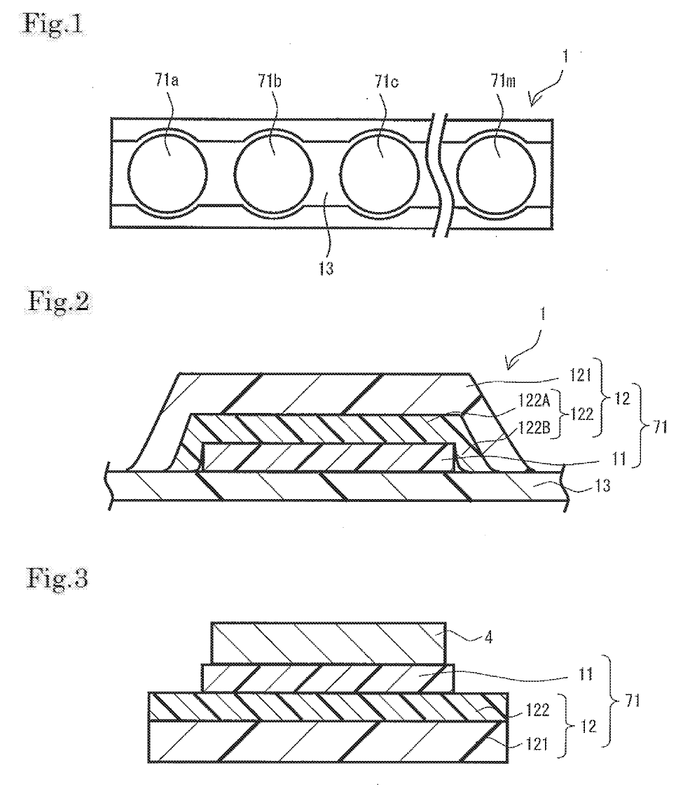

As shown in FIG. 1 and FIG. 2, composite body 1 comprises release liner 13 and laminated bodies 71a, 71b, 71c, . . . 71m (hereinafter collectively referred to as “laminated bodies 71”) which are arranged over release liner 13. The distance between laminated body 71a and laminated body 71b, the distance between laminated body 71h and laminated body 71c, . . . and the distance between laminated body 71l and laminated body 71m, is constant. Composite body 1 may be in the form of a roll.

Laminated bodies 71 comprise dicing sheet 12 and semiconductor backside protective film 11 which is arranged over dicing sheet 12.

Dicing sheet 12 comprises base layer 121 and adhesive layer 122 arranged over base layer 121. Adhesive layer 122 comprises first portion 122A. First portion 122A is cured. First portion 122A is in contact with semiconductor backside protective film 11. Adhesive layer 122 further comprises second portion 122B arranged peripherally with respect to first portion 122A. Second portion 122B has a property such that it may be cured by means of an energy beam. As energy beam, ultraviolet beams and the like may be cited as examples. Second portion 122B is not in contact with semiconductor backside protective film 11.

### —Semiconductor Backside Protective Film 11—

The two sides of semiconductor backside protective film 11 may be defined such that there is a first principal plane and a second principal plane opposite the first principal plane. The first principal plane is in contact with adhesive layer 122. The second principal plane is in contact with release liner 13.

Semiconductor backside protective film 11 is in an uncured state. Uncured state includes semicured state. A semicured state is preferred.

Tensile storage modulus of cured semiconductor backside protective film 11 is not less than 1 GPa over the entire range 23° C. to 80° C. Because this is not less than 1 GPa, it is possible to reduce cracking that would otherwise occur at the chip side face during dicing. It is preferred that this be not less than 2 GPa. The tensile storage modulus of cured semiconductor backside protective film 11 may be adjusted by means of acrylic resin content, thermosetting resin content, and so forth. Note that semiconductor backside protective film 11 may be cured by heating for 2 hours at 120° C. The tensile storage modulus of cured semiconductor backside protective film 11 is measured in accordance with the method described at the working examples.

It is preferred that the tensile storage modulus at 23° C. of cured semiconductor backside protective film 11 be not less than 2 GPa, and more preferred that this be not less than 2.5 GPa. The upper limit of the range in values for the tensile storage modulus at 23° C. of cured semiconductor backside protective film 11 might, for example, be 50 GPa, 10 GPa, 7 Gpa, or 5 GPa. And the upper limit of the range in values for the tensile storage modulus at 80° C. of cured semiconductor backside protective film 11 might, for example, be 50 GPa, 10 GPa, 7 Gpa, or 5 GPa.

It is preferred that the ratio of the tensile storage modulus at 80° C. of cured semiconductor backside protective film 11 to the tensile storage modulus at 23° C. of cured semiconductor backside protective film 11 (tensile storage modulus at 80° C./tensile storage modulus at 23° C.) be not less than 0.3, and it is preferred that this be not less than 0.4. If this is below 0.3, the large change in modulus of elasticity as a function of temperature will result in increased tendency for cracking to occur at chip side faces. It is preferred that this ratio (tensile storage modulus at 80° C./tensile storage modulus at 23° C.) be not greater than 1.0, more preferred that this be not greater than 0.9, and still more preferred that this be not greater than 0.8.

Semiconductor backside protective film 11 is colored. If this is colored, it may be possible to easily distinguish between dicing sheet 12 and semiconductor backside protective film 11. It is preferred that semiconductor backside protective film 11 be black, blue, red, or some other deep color. It is particularly preferred that this be black. The reason for this is that this will facilitate visual recognition of laser mark(s).

The deep color means a dark color having L* that is defined in the L*a*b* color system of basically 60 or less (0 to 60), preferably 50 or less (0 to 50) and more preferably 40 or less (0 to 40).

The black color means a blackish color having L* that is defined in the L*a*b* color system of basically 35 or less (0 to 35), preferably 30 or less (0 to 30) and more preferably 25 or less (0 to 25). In the black color, each of a* and b* that is defined in the L*a*b* color system can be appropriately selected according to the value of L*. For example, both of a* and b* are preferably −10 to 10, more preferably −5 to 5, and especially preferably −3 to 3 (above all, 0 or almost 0).

L*, a*, and b* that are defined in the L*a*b* color system can be obtained by measurement using a colorimeter (tradename: CR-200 manufactured by Konica Minolta Holdings, Inc.). The L*a*b* color system is a color space that is endorsed by Commission Internationale de I'Eclairage (CIE) in 1976, and means a color space that is called a CIE1976 (L*a*b*) color system. The L*a*b* color system is provided in JIS Z 8729 in the Japanese Industrial Standards.

It is preferred that moisture absorptivity of semiconductor backside protective film 11 when allowed to stand for 168 hours under conditions of 85° C. and 85% RH be not greater than 1 wt %, and it is more preferred that this be not greater than 0.8 wt %. By causing this to be not greater than 1 wt %, it is possible to improve laser marking characteristics. Moisture absorptivity can be controlled by means of inorganic filler content and so forth. A method for measuring moisture absorptivity of semiconductor backside protective film 11 is as follows. That is, semiconductor backside protective film 11 is allowed to stand for 168 hours in a constant-temperature/constant-humidity chamber at 85° C. and 85% RH, following which moisture absorptivity is determined from the percent weight loss as calculated based on measurements of weight before and after being allowed to stand.

It is preferred that moisture absorptivity of the cured substance obtained when semiconductor backside protective film 11 is cured and this is allowed to stand for 168 hours under conditions of 85° C. and 85% RH be not greater than 1 wt %, and it is more preferred that this be not greater than 0.8 wt %. By causing this to be not greater than 1 wt %, it is possible to improve laser marking characteristics. Moisture absorptivity can be controlled by means of inorganic filler content and so forth. A method for measuring moisture absorptivity of the cured substance is as follows. That is, the cured substance is allowed to stand for 168 hours in a constant-temperature/constant-humidity chamber at 85° C. and 85% RH, following which moisture absorptivity is determined from the percent weight loss as calculated based on measurements of weight before and after being allowed to stand.

The smaller the percentage of volatile components present in semiconductor backside protective film 11 the better. More specifically, it is preferred that the percent weight loss (fractional decrease in weight) of semiconductor backside protective film 11 following heat treatment be not greater than 1 wt %, and it is more preferred that this be not greater than 0.8 wt %. Conditions for carrying out heat treatment might, for example, be 1 hour at 250° C. Causing this to be not greater than 1 wt % will result in good laser marking characteristics. There may be reduced occurrence of cracking during the reflow operation. What is referred to as percent weight loss is the value obtained when semiconductor backside protective film 11 is thermally cured and is thereafter heated at 250° C. for 1 hour.

It is preferred that the tensile storage modulus at 23° C. of semiconductor backside protective film 11 when in an uncured state be not less than 1 GPa. Causing this to be not less than 1 GPa will make it possible to prevent semiconductor backside protective film 11 from adhering to the carrier tape. The upper limit of the range in values for the tensile storage modulus at 23° C. thereof might, for example, be 50 GPa. The tensile storage modulus at 23° C. thereof can be controlled by means of the type(s) of resin component(s) and amount(s) in which present, the type(s) of filler(s) and amount(s) in which present, and so forth. Tensile storage modulus is measured using a “Solid Analyzer RS A2” dynamic viscoelasticity measuring device manufactured by Rheometric, Inc., in tensile mode, with sample width=10 mm, sample length=22.5 mm, sample thickness=0.2 mm, frequency=1 Hz, and temperature rise rate=10° C./min in a nitrogen atmosphere at prescribed temperature (23° C.).

While there is no particular limitation with respect to the optical transmittance for a visible light beam (wavelength=380 nm to 750 nm) (visible light transmittance) of semiconductor backside protective film 11, it is for example preferred that this be within a range such that it is not greater than 20% (0% to 20%), more preferred that this be not greater than 10% (0% to 10%), and especially preferred that this be not greater than 5% (0% to 5%). If semiconductor backside protective film 11 has a visible light transmittance that is greater than 20%, there is a possibility that this will have an adverse effect on the semiconductor chip(s) due to passage of light beam(s) therethrough. Furthermore, the visible light transmittance (%) thereof can be controlled by means of the type(s) of resin component(s) and amount(s) in which present, the type(s) of colorant(s) (pigment(s), dye(s), and/or the like) and amount(s) in which present, the amount(s) in which inorganic filler(s) are present, and so forth at semiconductor backside protective film 11.

Visible light transmittance (%) of semiconductor backside protective film 11 may be measured as follows. That is, semiconductor backside protective film 11, of thickness (average thickness) 20 μm, is fabricated by itself. Next, the semiconductor backside protective film 11 is irradiated with a visible light beam of wavelength=380 nm to 750 nm (device=visible light generator manufactured by Shimadzu Corporation; product name “ABSORPTION SPECTRO PHOTOMETER”) and prescribed intensity, and intensity of the visible light beam that is transmitted therethrough is measured. Moreover, the value for visible light transmittance may be determined from the change in intensity as calculated based on measurements of a visible light beam before and after being transmitted through semiconductor backside protective film 11.

It is preferred that semiconductor backside protective film 11 comprise colorant. Colorant might, for example, be dye(s) and/or pigment(s). Of these, dye(s) are preferred, and black dye(s) are more preferred.

It is preferred that colorant(s) be present in semiconductor backside protective film 11 in an amount that is not less than 0.5 wt %, more preferred that this be not less than 1 wt %, and still more preferred that this be not less than 2 wt %. It is preferred that colorant(s) be present in semiconductor backside protective film 11 in an amount that is not greater than 10 wt %, more preferred that this be not greater than 8 wt %, and still more preferred that this be not greater than 5 wt %.

Semiconductor backside protective film 11 comprises a resin component. This might, for example, be thermoplastic resin, thermosetting resin, and/or the like.

As thermoplastic resin, natural rubber; butyl rubber; isoprene rubber; chloroprene rubber; ethylene-vinyl acetate copolymer; ethylene-acrylic acid copolymer; ethylene-acrylic acid ester copolymer; polybutadiene resin; polycarbonate resin; thermoplastic polyimide resin; nylon 6, nylon 6,6, and other such polyamide resins; phenoxy resin; acrylic resin; PET (polyethylene terephthalate), PBT (polybutylene terephthalate), and other such saturated polyester resins; polyamide-imide resin; fluorocarbon resin; and the like may be cited as examples. Any one of these thermoplastic resins may be used alone, or two or more species chosen from thereamong may be used in combination. Of these, acrylic resin is preferred.

It is preferred that acrylic resin be present at semiconductor backside protective film 11 in an amount that is not less than 0.1 wt % within 100 wt % of the resin component, more preferred that this be not less than 1 wt %, and still more preferred that this be not less than 5 wt %. It is preferred that acrylic resin be present in an amount that is not greater than 30 wt % within 100 wt % of the resin component, and it is more preferred that this be not greater than 25 wt %. If this is not greater than 30 wt %, it will be possible to prevent pieces of post-dicing semiconductor backside protective film from sticking to one another. Cleavage will also be good.

As thermosetting resin, epoxy resin, phenolic resin, amino resin, unsaturated polyester resin, polyurethane resin, silicone resin, thermosetting polyimide resin, and so forth may be cited as examples. Any one of these thermosetting resins may be used alone, or two or more species chosen from thereamong may be used in combination. As thermosetting resin, epoxy resin having low content of ionic impurities and/or other substances causing corrosion of semiconductor chips is particularly preferred. Furthermore, as curing agent for epoxy resin, phenolic resin may be preferably employed.

The epoxy resin is not especially limited, and examples thereof include bifunctional epoxy resins and polyfunctional epoxy resins such as a bisphenol A type epoxy resin, a bisphenol F type epoxy resin, a bisphenol S type epoxy resin, a brominated bisphenol A type epoxy resin, a hydrogenated bisphenol A type epoxy resin, a bisphenol AF type epoxy resin, a bisphenyl type epoxy resin, a naphthalene type epoxy resin, a fluorene type epoxy resin, a phenol novolak type epoxy resin, an ortho-cresol novolak type epoxy resin, a trishydroxyphenylmethane type epoxy resin, and a tetraphenylolethane type epoxy resin, a hydantoin type epoxy resin, a triglycidylisocyanurate type epoxy resin, and a glycidylamine type epoxy resin.

The phenolic resin acts as a curing agent for the epoxy resin, and examples thereof include novolak type phenolic resins such as a phenol novolak resin, a phenol aralkyl resin, a cresol novolak resin, a ten-butylphenol novolak resin, and a nonylphenol novolak resin, a resol type phenolic resin, and polyoxystyrenes such as polyparaoxystyrene. The phenolic resins can be used alone or two types or more can be used together. Among these phenolic resins, a phenol novolak resin and a phenol aralkyl resin are especially preferable because connection reliability in a semiconductor device can be improved.

The phenolic resin is suitably compounded in the epoxy resin so that a hydroxyl group in the phenolic resin to 1 equivalent of an epoxy group in the epoxy resin component becomes 0.5 to 2.0 equivalents. The ratio is more preferably 0.8 to 1.2 equivalents.

It is preferred that epoxy resin and phenolic resin be present in a combined amount that is not less than 70 wt % within 100 wt % of the resin component, and it is more preferred that this be not less than 75 wt %. It is preferred that epoxy resin and phenolic resin be present in a combined amount that is not greater than 99.9 wt % within 100 wt % of the resin component, more preferred that this be not greater than 99 wt %, and still more preferred that this be not greater than 95 wt %.

Semiconductor backside protective film 11 may comprise curing accelerator catalyst. For example, this might be amine-type curing accelerator, phosphorous-type curing accelerator, imidazole-type curing accelerator, boron-type curing accelerator, phosphorous-/boron-type curing accelerator, and/or the like.

To cause semiconductor backside protective film 11 to undergo crosslinking to a certain extent in advance, it is preferred that polyfunctional compound(s) that react with functional group(s) and/or the like at end(s) of polymer molecule chain(s) be added as crosslinking agent at the time of fabrication thereof. This will make it possible to improve adhesion characteristics at high temperatures and to achieve improvements in heat-resistance.

Semiconductor backside protective film 11 may comprise filler. Inorganic filler is preferred. This inorganic filler might, for example, be silica, clay, gypsum, calcium carbonate, barium sulfate, alumina, beryllium oxide, silicon carbide, silicon nitride, aluminum, copper, silver, gold, nickel, chromium, lead, tin, zinc, palladium, solder, and/or the like. Any one of these fillers may be used alone, or two or more species chosen from thereamong may be used in combination. Of these, silica is preferred, and fused silica is particularly preferred. It is preferred that average particle diameter of inorganic filler be within the range 0.1 μm to 80 μm. Average particle diameter of inorganic filler might, for example, be measured using a laser-diffraction-type particle size distribution measuring device.

It is preferred that filler be present in semiconductor backside protective film 11 in an amount that is not less than 10 wt %, more preferred that this be not less than 20 wt %, and still more preferred that this be not less than 30 wt %. It is preferred that filler be present in semiconductor backside protective film 11 in an amount that is not greater than 70 wt %, and it is more preferred that this be not greater than 60 wt %, and it is still more preferred that this be not greater than 50 wt %.

Semiconductor backside protective film 11 may comprise other additive(s) as appropriate. As other additive(s), flame retardant, silane coupling agent, ion trapping agent, expander, antioxidizer, antioxidant, surface active agent, and so forth may be cited as examples.

It is preferred that thickness of semiconductor backside protective film 11 be not less than 2 μm, more preferred that this be not less than 4 μm, still more preferred that this be not less than 6 μm, and particularly preferred that this be not less than 10 μm. It is preferred that thickness of semiconductor backside protective film 11 be not greater than 200 μm, more preferred that this be not greater than 160 μm, still more preferred that this be not greater than 100 μm, and particularly preferred that this be not greater than 80 μm.

### —Dicing Sheet 12—

Dicing sheet 12 comprises base layer 121 and adhesive layer 122 arranged over base layer 121.

It is preferred that thickness of adhesive layer 122 be not less than 3 μm, and more preferred that this be not less than 5 μm. It is preferred that thickness of adhesive layer 122 be not greater than 50 μm, and more preferred that this be not greater than 30 μm.

Adhesive layer 122 is formed from adhesive. The adhesive might, for example, acrylic adhesive and/or rubber-type adhesive. Of these, acrylic adhesive is preferred. The acrylic adhesive might, for example, be an acrylic adhesive in which the base polymer thereof is an acrylic polymer (homopolymer or copolymer) employing one, two, or more varieties of (meth)acrylic acid alkyl ester as monomer component(s).

It is preferred that thickness of base layer 121 be 50 μm s to 150 μm. It is preferred that base layer 121 have a property such that an energy beam is transmitted therethrough.

### —Release Liner 13—

Release liner 13 might, for example, be polyethylene terephthalate (PET) film.

### —Semiconductor Device Manufacturing Method—

As shown in FIG. 3, semiconductor wafer 4 is secured to semiconductor backside protective film 11 of laminated bodies 71. More specifically, a pressure roller or other such pressure-applying means is used to compression-bond laminated bodies 71 onto semiconductor wafer 4 at 50° C. to 100° C. The two sides of semiconductor wafer 4 may be defined such that there is a circuit side and a backside (also referred to as non-circuit side or non-electrode-forming side) opposite the circuit side. Semiconductor wafer 4 might, for example, be a silicon wafer.

Application of heat to semiconductor backside protective film 11 causes curing of semiconductor backside protective film 11. For example, a heater might be directed at dicing sheet 12 to cause semiconductor backside protective film 11 to be heated by heat which is made to pass through dicing sheet 12.

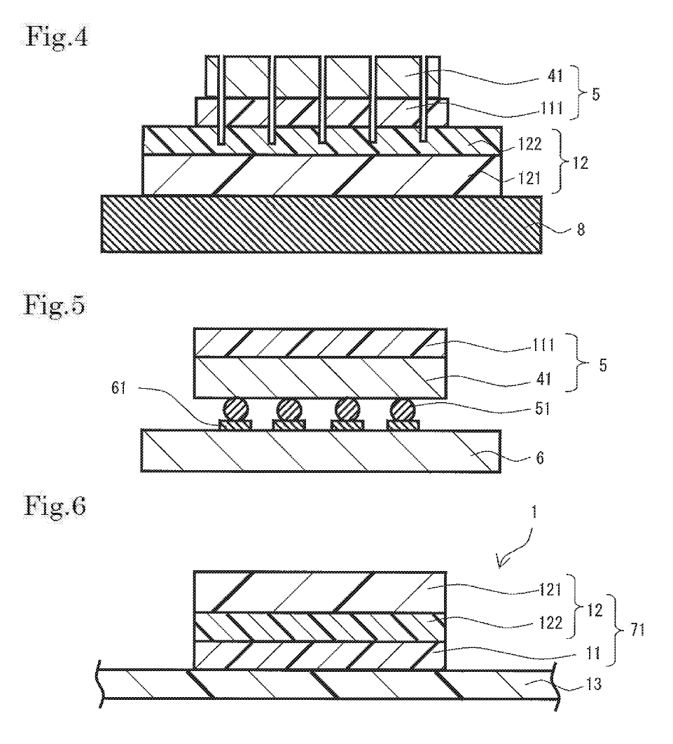

As shown in FIG. 4, dicing sheet 12 is secured to suction plate 8, and semiconductor wafer 4 is cut to form assemblies 5. That is, assemblies 5 are formed as a result of dicing of semiconductor wafer 4. Assembly 5 comprises semiconductor chip 41 and post-dicing semiconductor backside protective film 111 which is secured to the backside of semiconductor chip 41. The two sides of semiconductor chip 41 may be defined such that there is a circuit side and a backside opposite the circuit side. Assembly 5 is secured to dicing sheet 12.

Needle(s) are used to push up assembly 5, and assembly 5 is detached from dicing sheet 12.

As shown in FIG. 5, the flip-chip bonding technique (flip-chip mounting technique) is employed to cause assembly 5 to be secured to object 6 to be bonded. More specifically, assembly 5 is secured to object 6 to be bonded in such fashion that the circuit side of semiconductor chip 41 is opposed to object 6 to be bonded. For example, bump 51 of semiconductor chip 41 might be made to conic in contact with electrically conductive material (solder or the like) 61 of object 6 to be bonded, and while pushing this thereagainst, electrically conductive material 61 might be made to melt. There is a gap between assembly 5 and object 6 to be bonded. Height of this gap might typically be on the order of 30 μm to 300 μm. Following securing of constituent parts, it is possible to carry out cleaning of the gap and so forth.

As object 6 to be bonded, a lead frame, circuit board (wiring circuit board), or other such substrate may be employed. As material for such substrate, while there is no particular limitation with respect thereto, ceramic substrate and plastic substrate may be cited as examples. As plastic substrate, epoxy substrate, bismaleimide triazine substrate, polyimide substrate, and the like may be cited as examples.

As material for the bump and/or electrically conductive material, there is no particular limitation with respect thereto, it being possible to cite examples that include tin-lead-type metallic materials, tin-silver-type metallic materials, tin-silver-copper-type metallic materials, tin-zinc-type metallic materials, tin-zinc-bismuth-type metallic materials, and other such solders (alloys); gold-type metallic materials; and copper-type metallic materials. Note that temperature at the time of melting of electrically conductive material 61 might ordinarily be on the order of 260° C. If post-dicing semiconductor backside protective film 111 comprises epoxy resin, it will be able to withstand such temperatures.

The gap between assembly 5 and object 6 to be bonded is sealed with resin sealant. Resin sealant might ordinarily be cured by heating for 60 seconds to 90 seconds at 175° C.

As resin sealant, so long as it is a resin that has insulating characteristics (insulating resin), there is no particular limitation with respect thereto. As resin sealant, it is more preferred that this be an insulating resin that has elasticity. As resin sealant, resin compositions comprising epoxy resins and the like may be cited as examples. Furthermore, as resin sealant which is a resin composition comprising epoxy resin, the resin component thereof may, besides epoxy resin, comprise thermosetting resin other than epoxy resin (phenolic resin and/or the like), thermoplastic resin, and/or the like. Where phenolic resin is employed, note that this may also serve as curing agent for epoxy resin. Resin sealant may take the form of sheet(s), tablet(s), and/or the like.

A semiconductor device (flip-chip-mounted semiconductor device) manufactured in accordance with the foregoing method comprises object 6 to be bonded and assembly 5 secured to object 6 to be bonded.

A laser may be used to carry out marking of post-dicing semiconductor backside protective film 111 of the semiconductor device. Note that known laser marking apparatuses may be employed when carrying out laser marking. Furthermore, as laser, gas lasers, solid-state lasers, liquid lasers, and the like may be employed. More specifically, as gas laser, while there is no particular limitation with respect thereto and any known gas laser may be employed, carbon dioxide gas lasers (CO₂ lasers) and excimer lasers (ArF lasers. KrF lasers, XeCl lasers, XeF lasers, etc.) are preferred. Furthermore, as solid-state laser, while there is no particular limitation with respect thereto and any known solid-state laser may be employed, YAG lasers (Nd:YAG lasers, etc.) and YVO₄ lasers are preferred.

A semiconductor device in which semiconductor elements are mounted in a flip chip bonding manner is thinner and smaller than a semiconductor device in which semiconductor elements are mounted in a die bonding manner. For this reason, the former semiconductor device is appropriately usable for various electric instruments or electronic components, or as a component or member of these instruments or components. Specifically, an electronic instrument in which the flip-chip-bonded semiconductor device is used is, for example, the so-called “portable telephone” or “PHS”, a small-sized computer (such as the so-called “PDA” (portable data assistant), the so-called “laptop computer”, the so-called “net book (trademark)”, or the so-called “wearable computer”), a small-sized electronic instrument to which a “portable telephone” and a computer are integrated, the so-called “digital camera (trademark)”, the so-called “digital video camera”, a small-sized television, a small-sized game machine, a small-sized digital audio player, the so-called “electronic notebook”, the so-called “electronic dictionary”, the so-called electronic instrument terminal for “electronic dictionary”, a small-sized digital-type clock, or any other mobile type electronic instrument (portable electronic instrument). Of course, the electronic instrument may be, for example, an electronic instrument of a type (setup type) other than any mobile type (this instrument being, for example, the so-called “disk top computer”, a thin-type television, an electronic instrument for recording and reproduction (such as a hard disk recorder or a DVD player), a projector, or a micro machine). An electronic component in which the flip-chip-bonded semiconductor device is used, or such a component or member of an electronic instrument or electronic component is, for example, a member of the so-called “CPU”, or a member of a memorizing unit (such as the so-called “memory”, or a hard disk) that may be of various types.

### —Variation 1—

First portion 122A of adhesive layer 122 has a property such that it may be cured by means of an energy beam. Second portion 122B of adhesive layer 122 also has a property such that it may be cured by means of an energy beam. At Variation 1, following the operation in which assembly 5 is formed, adhesive layer 122 is irradiated with an energy beam and pick-up of assembly 5 is carried out. Irradiating this with an energy beam facilitates pick-up of assembly 5.

### —Variation 2—

First portion 122A of adhesive layer 122 is cured by means of an energy beam. Second portion 122B of adhesive layer 122 is also cured by means of an energy beam.

### —Variation 3—

As shown in FIG. 6, the entire surface of one side of adhesive layer 122 is in contact with semiconductor backside protective film 11.

### —Miscellaneous—

Any of Variation 1 through Variation 3 and/or the like may be combined as desired.

A method for manufacturing a semiconductor device associated with Embodiment 1 as described above comprises Operation (A) in which semiconductor wafer 4 is secured to semiconductor backside protective film 11 of laminated bodies 71; Operation (B) in which semiconductor backside protective film 11 is cured following Operation (A); Operation (C) in which semiconductor water 4 which has semiconductor backside protective film 11 secured thereto is subjected to dicing to form assemblies 5 following Operation (B); and Operation (D) in which assemblies 5 are detached from dicing sheet 12.

### WORKING EXAMPLES

Below, exemplary detailed description of this invention is given in terms of preferred working examples. Note, however, that except where otherwise described as limiting, the materials, blended amounts, and so forth described in these working examples are not intended to limit the scope of the present invention thereto.

### Working Example 1

### —Fabrication of Semiconductor Backside Protective Film—

For every 100 parts by weight of the solids content—i.e., solids content exclusive of solvent—of acrylic-acid-ester-type polymer (Paracron W-197C; manufactured by Negami Chemical Industrial Co., Ltd) having ethyl acrylate and methyl methacrylate as principal constituents, 300 parts by weight of epoxy resin (jER YL980; manufactured by Mitsubishi Chemical Corporation), 130 parts by weight of epoxy resin (KI-3000; manufactured by Tohto Chemical Industry Co., Ltd.), 460 parts by weight of phenolic resin (MEH7851-SS; manufactured by Meiwa Plastic Industries, Ltd.), 690 parts by weight of spherical silica (SO-25R; spherical silica having average particle diameter 0.5 μm; manufactured by Admatechs Company Limited), 10 parts by weight of dye (OIL BLACK BS; manufactured by Orient Chemical Industries Co., Ltd.), and 80 parts by weight of catalyst (2 PHZ; manufactured by Shikoku Chemicals Corporation) were dissolved in methyl ethyl ketone to prepare a resin composition solution having a solids concentration of 23.6 wt %. The resin composition solution was applied to a release liner (polyethylene terephthalate film of thickness 50 μm which had been subjected to silicone mold release treatment), and this was dried for 2 minutes at 130° C. In accordance with the foregoing means, a film of average thickness 20 μm was obtained. A disk-shaped piece of film (hereinafter referred to in the Working Examples as “Semiconductor Backside Protective Film”) of diameter 330 mm was cut out of the film.

### —Fabrication of Laminated Body—

A hand roller was used to apply Semiconductor Backside Protective Film to a dicing sheet (V7-8-AR; manufactured by Nitto Denko Corporation; dicing sheet comprising base layer of average thickness 65 μm and adhesive layer of average thickness 10 μm) to fabricate a laminated body in accordance with Working Example 1. The laminated body in accordance with Working Example 1 comprised a dicing sheet and a semiconductor backside protective film secured to the adhesive layer.

### Working Examples 2 and 3; Comparative Examples 1 and 2

Except for the fact that Semiconductor Backside Protective Film was fabricated as indicated by the blended amounts listed at TABLE 1, the laminated bodies of Working Examples 2 and 3, and of Comparative Examples 1 and 2, were fabricated using methods identical to that at Working Example 1.

### Evaluation 1: Post-Curing Tensile Storage Modulus E′

Semiconductor Backside Protective Film was heated for 2 hours at 120° C., and the release liner was removed therefrom. A sample 10 mm in width, 22.5 mm in length, and 0.02 mm in thickness was cut from the Semiconductor Backside Protective Film following heating thereof. Dynamic viscoelasticity measurements were carried out from 0° C. to 100° C. using a “Solid Analyzer RS A2” dynamic viscoelasticity measuring device manufactured by Rheometric, Inc., in tensile mode at a frequency of 1 Hz and a temperature rise rate of 10° C./min in a nitrogen atmosphere. Tensile storage modulus was evaluated as GOOD if it was not less than 1 GPa over the entire range 23° C. to 80° C. This was evaluated as BAD otherwise. Results are shown in TABLE 1.

### Evaluation 2: Chipping.

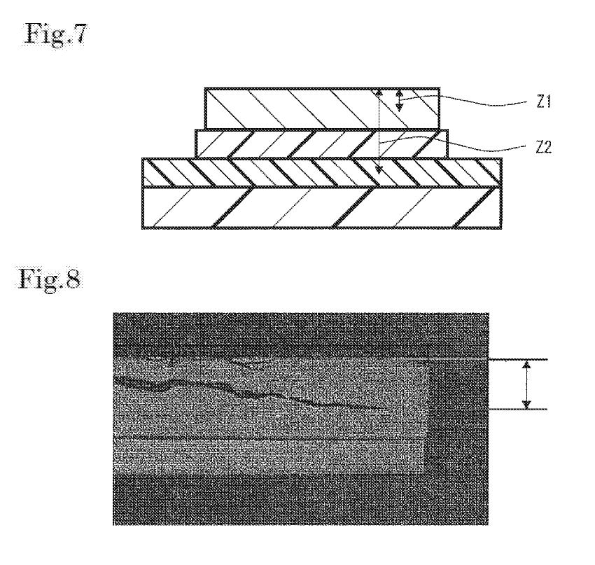

A wafer (silicon mirror wafer of thickness 0.2 mm, diameter 8 inches, the backside of which had been subjected to polishing treatment) was compression-bonded at 70° C. to the semiconductor backside protective film of the laminated body. The wafer which was secured to the laminated body was subjected to dicing to form assemblies—each of which respectively comprised a silicon chip and post-dicing semiconductor backside protective film secured to the silicon chip. As shown in FIG. 7, adjustment was carried out so as to obtain a cut depth Z1—depth from the surface of the silicon chip—of 45 μm. Adjustment of cut depth Z2 was carried out so as to obtain a cut depth Z2 that extended into the adhesive layer of the dicing tape by one half-thickness thereof.

### —Wafer Grinding Conditions—

Grinding apparatus: Product name “DFG-8560” manufactured by Disco Corporation

### —Laminating Conditions—

Laminating apparatus: Product name “MA-3000III” manufactured by Nitto Seiki Co., Ltd.

Laminating speed indicator: 10 mm/min

Laminating pressure: 0.15 MPa

Stage temperature during lamination: 70° C.

### —Dicing Conditions—

Dicing apparatus: Product name “DFD-6361” manufactured by Disco Corporation

Dicing ring: “2-8-1” (Disco Corporation)

Dicing speed: 30 mm/sec
Dicing blades:
   Z1: “2030-SE 27HCDD” manufactured by Disco Corporation
   Z2: “2030-SE 27HCBB” manufactured by Disco Corporation
Dicing blade rotational speed:
   Z1: 40,000 r/min
   Z2: 45,000 r/min
Cutting method: Step-cut
   Chip size, 2.0 mm square

The assemblies were detached from the dicing sheet. A microscope (VHX500; manufactured by Keyence Corporation) was used to observe the cut surface of the silicon chip—the surface which of the four cut surfaces was the last to be cut—and crack depth was measured. As shown in FIG. 8, crack depth was the depth from the interface between Semiconductor Backside Protective Film and the silicon chip. Crack depth was evaluated as EXCELLENT if it was less than 10% on a scale for which 100% corresponded to the silicon chip thickness. Crack depth was evaluated as GOOD if it was less than 30%. Crack depth was evaluated as BAD if it was 30% or greater. Results are shown in TABLE 1.

TABLE 1

| | | | | |
|---|---|---|---|---|
| Working | Working | Working | Comparative | Comparative |
| Example 1 | Example 2 | Example 3 | Example 1 | Example 2 |

Amounts of Constituents in
Semiconductor Backside Protective Film

| | | | | | | |
|---|---|---|---|---|---|---|
| Amount | Acrylic resin (Paracron W- | 100 | 100 | 100 | 100 | 100 |
| (parts | 197C) | | | | | |
| by | Epoxy resin (jER YL980) | 300 | 85 | 60 | 20 | — |
| weight) | Epoxy resin (KI-3000) | 130 | 190 | 140 | 50 | — |
| | Epoxy resin (HP-4700) | — | — | — | — | 10 |
| | Phenolic resin (MEH7851- | 460 | 290 | 200 | 75 | — |
| | SS) | | | | | |
| | Phenolic resin (MEH7851-H) | — | — | — | — | 10 |
| | Spherical silica (SO-25R) | 690 | 450 | 340 | 180 | 85 |
| | Dye (OIL BLACK BS) | 10 | 10 | 10 | 10 | 10 |
| | Catalyst (2PHZ) | 80 | 55 | 40 | 20 | 10 |

| | | | | | |
|---|---|---|---|---|---|
| Total | 1770.0 | 1180.0 | 890.0 | 455.0 | 225.0 |
| Amount in wt % of acrylic resin within | 10 | 15 | 20 | 41 | 83 |
| 100 wt % of resin component | | | | | |

Evaluation

| | | | | | |
|---|---|---|---|---|---|
| Post-curing tensile storage modulus at | GOOD | GOOD | GOOD | BAD | BAD |
| 23° C. to 80° C. | | | | | |
| Post-curing tensile storage modulus at | 4.88 | 3.48 | 2.65 | 1.39 | 1.67 |
| 23° C. (GPa) | | | | | |
| Post-curing tensile storage modulus at | 4.05 | 2.00 | 1.05 | 0.53 | 0.01 |
| 80° C. (GPa) | | | | | |
| Ratio of tensile storage modulus at | 0.8 | 0.6 | 0.4 | 0.4 | 0.01 |
| 80° C. to tensile storage modulus | | | | | |
| at 23° C. | | | | | |
| Chipping | EXCELLENT | EXCELLENT | GOOD | BAD | BAD |

### EXPLANATION OF REFERENCE NUMERALS

1 Composite body
11 Semiconductor backside protective film
12 Dicing sheet
121 Base layer
122 Adhesive layer
122A First portion
122B Second portion
13 Release liner
71 Laminated bodies
4 Semiconductor wafer
5 Assembly
6 Object to be bonded
8 Suction plate
41 Semiconductor chip
51 Bump
61 Electrically conductive material
111 Post-dicing semiconductor backside protective film

1. A laminated body comprising:
a dicing sheet comprising a base layer and an adhesive layer arranged over the base layer; and
a semiconductor backside protective film arranged over the adhesive layer;
wherein tensile storage modulus of semiconductor backside protective film following curing is not less than 1 GPa over the entire range 23° C. to 80° C.

2. A laminated body according to claim 1 wherein a ratio of tensile storage modulus at 80° C. of the semiconductor backside protective film following curing to tensile storage modulus at 23° C. of the semiconductor backside protective film following curing is 0.3 to 1.0.

3. A laminated body according to claim 1 wherein
the semiconductor backside protective film comprises a resin component;
the resin component comprises acrylic resin, epoxy resin, and phenolic resin;
the acrylic resin is present in an amount that is 0.1 wt % to 30 wt % within 100 wt % of the resin component.

4. A composite body comprising
a release liner; and
the laminated body according to claim 1 arranged over the release liner.

5. A semiconductor device manufacturing method comprising:
an operation in which a semiconductor wafer is secured to the semiconductor backside protective film of the laminated body according to claim 1;
an operation in which, following the operation in which the semiconductor wafer is secured to the semiconductor backside protective film of the laminated body, the semiconductor backside protective film is cured;
an operation in which, following the operation in which the semiconductor backside protective film is cured, the semiconductor wafer secured to the semiconductor backside protective film is subjected to dicing to form an assembly comprising a semiconductor chip and a post-dicing semiconductor backside protective film secured to the semiconductor chip; and
an operation in which the assembly is detached from the dicing sheet.
